(19) United States
(12) Patent Application Publication
(10) Pub. No.: US 2026/0114191 A1
(43) Pub. Date: Apr. 23, 2026

(54) SUBSTRATE PROCESSING METHOD AND SUBSTRATE PROCESSING APPARATUS

(71) Applicant: Tokyo Electron Limited, Tokyo (JP)

(72) Inventors: Tuhin Shuvra Basu, Albany, NY (US); Hiroto FUJIKAWA, Yamanashi (JP); Keita KUMAGAI, Yamanashi (JP); Atsushi ENDO, Yamanashi (JP)

(21) Appl. No.: 19/353,040

(22) Filed: Oct. 8, 2025

(30) Foreign Application Priority Data
Oct. 21, 2024 (JP) 2024-185031

(51) Int. Cl. H01L 21/02; H01L 21/67

(52) U.S. Cl. CPC H10P 14/3411; H10P 14/3802; H10P 72/0434; H10P 72/0602

(57) ABSTRACT

A substrate processing method includes providing a substrate including a first film that is amorphous, a first silicon-containing film that is amorphous and is not in contact with the first film, and a second silicon-containing film that is amorphous and is in contact with the first film, a crystallization temperature of the first film being lower than a crystallization temperature of the first silicon-containing film; and thermally processing the substrate at a temperature that is equal to or higher than the crystallization temperature of the first film and lower than the crystallization temperature of the first silicon-containing film.

### CROSS-REFERENCE TO RELATED APPLICATIONS

This application is based upon and claims priority to Japanese Patent Application No. 2024-185031, filed on Oct. 21, 2024, the entire contents of which are incorporated herein by reference.

### BACKGROUND

### 1. Field of the Invention

The present disclosure relates to a substrate processing method and a substrate processing apparatus.

### 2. Description of the Related Art

Japanese Laid-Open Patent Application Publication No. 2020-87993 discloses a technique in which an amorphous germanium film is formed over an amorphous silicon film, followed by performing thermal processing at an appropriate temperature, thereby crystallizing the amorphous germanium film and then crystallizing the amorphous silicon film.

### SUMMARY

A substrate processing method according to an aspect of the present disclosure includes: providing a substrate including a first film that is amorphous, a first silicon-containing film that is amorphous and is not in contact with the first film, and a second silicon-containing film that is amorphous and is in contact with the first film, a crystallization temperature of the first film being lower than a crystallization temperature of the first silicon-containing film; and thermally processing the substrate at a temperature that is equal to or higher than the crystallization temperature of the first film and lower than the crystallization temperature of the first silicon-containing film.

### BRIEF DESCRIPTION OF THE DRAWINGS

FIG. 1 is a flowchart illustrating a substrate processing method according to an embodiment of the present disclosure.

FIG. 2 is a cross-sectional diagram (1) illustrating the substrate processing method according to the embodiment.

FIG. 3 is a cross-sectional diagram (2) illustrating the substrate processing method according to the embodiment.

FIG. 4 is a cross-sectional diagram (3) illustrating the substrate processing method according to the embodiment.

FIG. 5 is a vertical cross-sectional diagram illustrating a substrate processing apparatus according to an embodiment of the present disclosure.

FIG. 6 is a horizontal cross-sectional diagram illustrating the substrate processing apparatus according to the embodiment.

### DETAILED DESCRIPTION OF THE DISCLOSURE

The present disclosure provides a technique that is capable of selectively crystallizing a silicon-containing film.

Hereinafter, non-limiting exemplary embodiments of the present disclosure will be described with reference to the attached drawings. In the drawings, the same or corresponding members or parts will be denoted by the same or corresponding reference symbols, and thus duplicate description thereof will be omitted.

### [Substrate Processing Method]

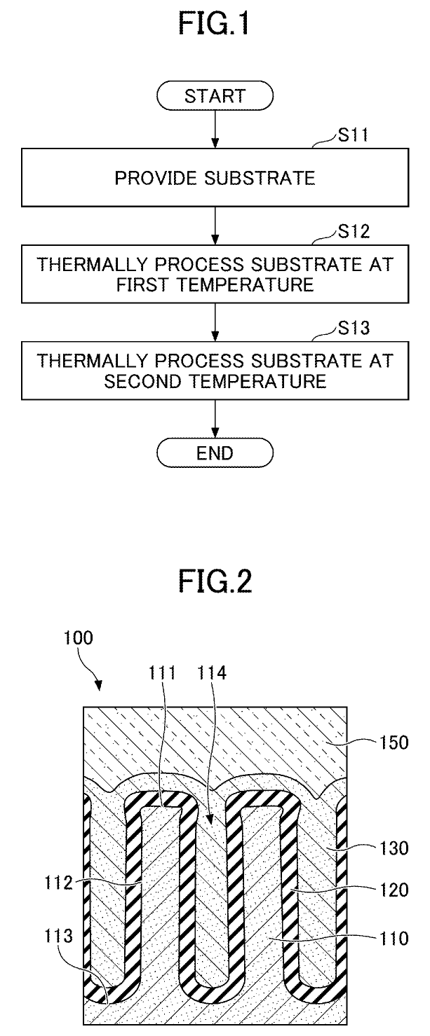

A substrate processing method according to an embodiment of the present disclosure will be described with reference to FIGS. 1 to 4. FIG. 1 is a flowchart illustrating the substrate processing method according to the embodiment. FIGS. 2 to 4 are cross-sectional diagrams illustrating the substrate processing method according to the embodiment. The substrate processing method according to the embodiment includes steps S11 to S13 illustrated in FIG. 1.

In step S11, a substrate 100 is provided as illustrated in FIG. 2. The substrate 100 includes a silicon film 110, a silicon oxide film 120, a silicon film 130, and a germanium film 150.

The silicon film 110 is amorphous. The silicon film 110 is a non-doped film. The silicon film 110 includes a top surface 111, a side surface 112 continuous with the top surface 111, and a bottom surface 113 continuous with the side surface 112. The silicon film 110 forms a recess 114 by the two adjacent side surfaces 112 and the bottom surface 113 continuous with both the two adjacent side surfaces 112. For example, the silicon film 110 can be formed through chemical vapor deposition (CVD) using a silicon raw material gas. The silicon film 110 is an example of a first silicon-containing film.

The silicon oxide film 120 is provided over the silicon film 110. The silicon oxide film 120 covers the top surface 111, the side surface 112, and the bottom surface 113 of the silicon film 110. The silicon oxide film 120 is provided along the top surface 111, the side surface 112, and the bottom surface 113 of the silicon film 110. The silicon oxide film 120 is provided not to close an opening of the recess 114. For example, the silicon oxide film 120 can be formed using a silicon raw material gas and an oxidizing gas through chemical vapor deposition, atomic layer deposition (ALD), or the like. The silicon oxide film 120 is an example of an insulating film.

The silicon film 130 is amorphous. The silicon film 130 is a non-doped film. The silicon film 130 is provided over the silicon oxide film 120. The silicon film 130 covers the surface of the silicon oxide film 120. The silicon film 130 is embedded in the recess 114. For example, the silicon film 130 can be formed through chemical vapor deposition using a silicon raw material gas. The silicon film 130 is an example of a second silicon-containing film.

The germanium film 150 is amorphous. The germanium film 150 is a non-doped film. The crystallization temperature of the germanium film 150 is lower than the crystallization temperature of the silicon film 110 and the crystallization temperature of the silicon film 130. The germanium film 150 is provided over the silicon film 130. The germanium film 150 covers the surface of the silicon film 130. The germanium film 150 is in contact with the silicon film 130. The germanium film 150 is provided such that the silicon oxide film 120 exists between the germanium film 150 and the silicon film 110. The germanium film 150 is not in contact with the silicon film 110. For example, the germanium film 150 can be formed through chemical vapor deposition using a germanium raw material gas. Before forming the germanium film 150, a process for removing a native oxide film on the surface of the silicon film 130 may be performed. The germanium film 150 is an example of a first film.

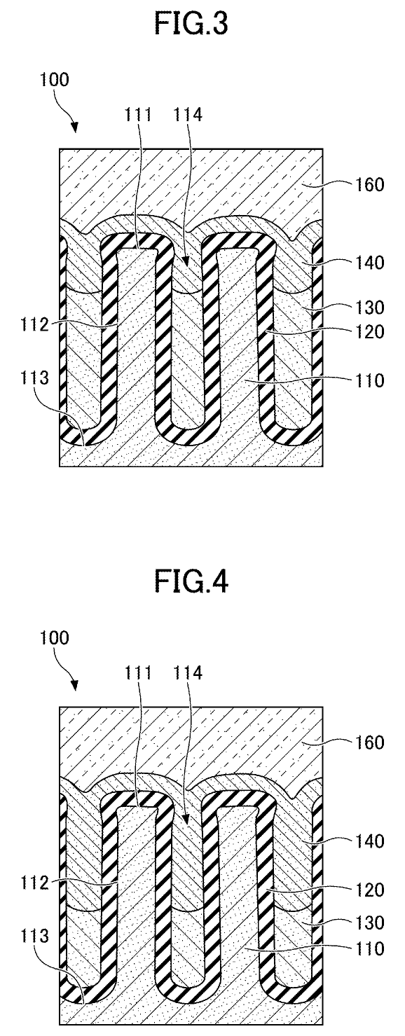

In step S12, the substrate 100 is thermally processed in a thermal processing gas atmosphere at a first temperature that is equal to or higher than the crystallization temperature of the germanium film 150 and lower than the crystallization temperature of the silicon film 110 and the crystallization temperature of the silicon film 130. Thus, as illustrated in FIG. 3, the germanium film 150 is crystallized to form a polycrystalline germanium film 160. Also, the crystallization of the germanium film 150 triggers crystallization of the silicon film 130, which begins at the interface between the polycrystalline germanium film 160 and the silicon film 130 and progresses from top to bottom, resulting in the formation of a polycrystalline silicon film 140. Differing from the silicon film 130, the silicon film 110 is not in contact with the germanium film 150. Therefore, even if the substrate 100 is thermally processed at the first temperature that is lower than the crystallization temperature of the silicon film 110, crystallization of the silicon film 110, which would otherwise be caused by the crystallization of the germanium film 150, does not occur, and thus the silicon film 110 is maintained to be amorphous. As a result, the silicon film 130 can be selectively crystallized relative to the silicon film 110. The first temperature is, for example, 450 degrees Celsius (°C.) or higher and 550°C or lower.

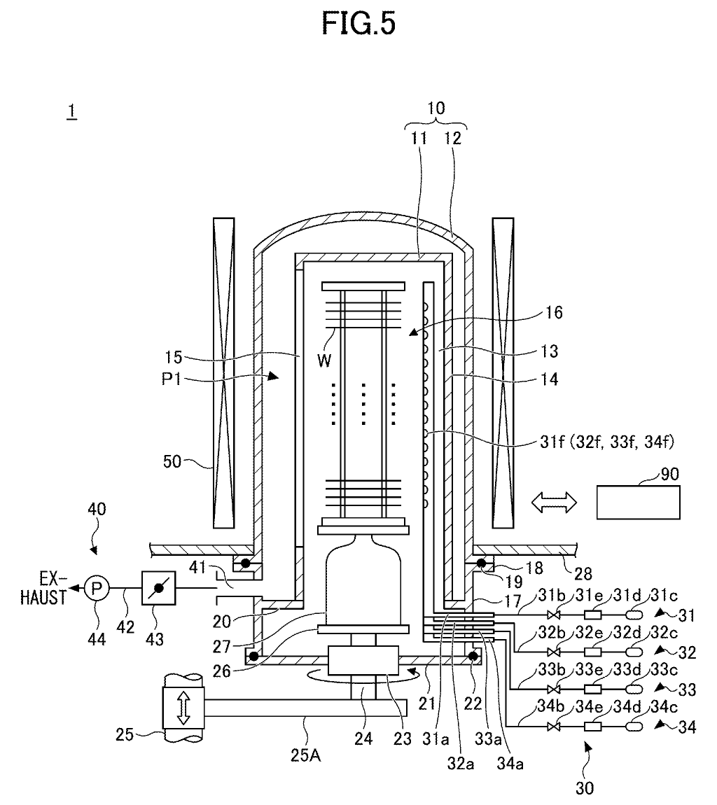

In step S13, the substrate 100 is thermally processed in a thermal processing gas atmosphere at a second temperature that is equal to or higher than the first temperature and lower than both the crystallization temperature of the silicon film 110 and the crystallization temperature of the silicon film 130. Thus, as illustrated in FIG. 4, the crystallization of the silicon film 130 progresses from the opening side toward the bottom side of the recess 114, thereby forming the polycrystalline silicon film 140 up to a deep position of the recess 114. In step S13, as in step S12, the silicon film 110 is maintained to be amorphous. As a result, the silicon film 130 can be selectively crystallized relative to the silicon film 110. The second temperature is, for example, 550° C. or higher and lower than 600° C. The substrate 100 is thermally processed at the second temperature until the polycrystalline silicon film 140 is formed up to a desired position, and then step S13 is ended. The desired position may be a position partway in a depth direction of the recess 114 or may be a position in contact with the bottom surface of the recess 114.

As described above, according to the substrate processing method according to the embodiment, first, in step S11, the substrate including the germanium film 150, the silicon film 110 not in contact with the germanium film 150, and the silicon film 130 in contact with the germanium film 150 is provided. Next, in step S12, the substrate 100 is thermally processed at the first temperature that is equal to or higher than the crystallization temperature of the germanium film 150 and lower than the crystallization temperature of the silicon film 110 and the crystallization temperature of the silicon film 130. In this case, in step S12, the germanium film 150 is crystallized to form the polycrystalline germanium film 160. Also, the crystallization of the germanium film 150 triggers crystallization of the silicon film 130, which begins at the interface between the polycrystalline germanium film 160 and the silicon film 130 and progresses from top to bottom, resulting in the formation of the polycrystalline silicon film 140. Differing from the silicon film 130, the silicon film 110 is not in contact with the germanium film 150. Therefore, even if the substrate 100 is thermally processed at the first temperature that is lower than the crystallization temperature of the silicon film 110, the crystallization of the silicon film 110, which would otherwise be caused by the crystallization of the germanium film 150, does not occur, and thus the silicon film 110 is maintained to be amorphous. As a result, the silicon film 130 can be selectively crystallized relative to the silicon film 110.

According to the substrate processing method according to the embodiment, in step S13, the substrate 100 is thermally processed at the second temperature that is equal to or higher than the first temperature and lower than both the crystallization temperature of the silicon film 110 and the crystallization temperature of the silicon film 130. By thermally processing the substrate 100 at the second temperature higher than the first temperature, it is possible to accelerate progression of the crystallization of the silicon film 130 compared to a case in which the substrate 100 is thermally processed only at the first temperature.

The substrate processing method according to the embodiment sequentially performs thermally processing the substrate 100 at the first temperature, and thermally processing the substrate 100 at the second temperature higher than the first temperature. The temperature for crystallizing the germanium film 150 may be lower than the temperature for progressing the crystallization of the silicon film 130. Therefore, by thermally processing the substrate 100 at a relatively low temperature in an initial stage of the thermal processing, it is possible to reduce a thermal influence on the substrate 100 compared to a case in which the substrate 100 is thermally processed at a relatively high temperature from the initial stage of the thermal processing.

Note that a process for removing the polycrystalline germanium film 160 may be performed after step S13. For example, the polycrystalline germanium film 160 can be removed by etching the polycrystalline germanium film 160 with dilute hydrofluoric acid to remove a native oxide film on the surface of the polycrystalline germanium film 160, and then etching the polycrystalline germanium film 160 with hydrogen peroxide. Also, for example, the polycrystalline germanium film 160 may be removed through dry etching using an etching gas. As the etching gas, Cl₂ is preferably used, but HCl, HBr, HI, Br₂, or I₂ may be used. However, when the polycrystalline silicon film 140 is a film used as a channel layer for a three-dimensional NAND, the polycrystalline germanium film 160 to be removed is not readily removed through dry etching because the polycrystalline germanium film 160 is formed on the inner wall of a recess having a high aspect ratio. Therefore, when the polycrystalline silicon film 140 is a film used as a channel layer for a three-dimensional NAND, it is preferable to remove the polycrystalline germanium film 160 through wet etching.

### [Type of Gas]

Specific examples of the gas used in the substrate processing method according to the embodiment will be described.

The silicon raw material gas used for forming the silicon film 110 and the silicon film 130 may be any gas as long as it is applicable to chemical vapor deposition. For example, the silicon raw material gas is, for example, a silane gas, a halogen-containing silicon gas, or an aminosilane-based gas, or any combination of a silane gas, a halogen-containing silicon gas, and an aminosilane-based gas. Examples of the silane gas include SiH₄, Si₂H₆, and Si₃H₈. Examples of the halogen-containing silicon gas include: fluorine-containing silicon gases, such as SiF₄, SiHF₃, SiH₂F₂, SiH₃F, and the like; chlorine-containing silicon gases, such as SiCl₄, SiHCl₃, SiH₂Cl₂, SiH₃Cl, and the like; and bromine-containing silicon gases, such as SiBr₄, SiHBr₃, SiH₂Br₂, SiH₃Br, and the like. Examples of the aminosilane-based gas include DIPAS (di(isopropylamino)silane), 3DMAS (tris(dimethylamino)silane), and BTBAS (bis(tert-butylamino)silane).

The silicon raw material gas used for forming the silicon oxide film 120 may be the silicon raw material gas used for forming the silicon film 110 and the silicon film 130. The oxidizing gas used for forming the silicon oxide film 120 may be O₂, O₃, H₂O, or NO₂, or any combination of O₂, O₃, H₂O, and NO₂.

The germanium raw material gas used for forming the germanium film 150 may be any gas as long as it is applicable to chemical vapor deposition. For example, the germanium raw material gas may be a germane gas, a halogen-containing germanium gas, or an aminogermane-based gas. Examples of the germane gas include GeH₄, Ge₂H₆, and Ge₃H₈. Examples of the halogen-containing germanium gas include: fluorine-containing germanium gases, such as GeF₄, GeHF₃, GeH₂F₂, GeH₃F, and the like; chlorine-containing germanium gases, such as GeCl₄, GeHCl₃, GeH₂Cl₂, GeH₃Cl, and the like; and bromine-containing gases, such as GeBr₄, GeHBr₃, GeH₂Br₂, GeH₃Br, and the like. Examples of the aminogermane-based gas include DMAG (di(methylamino)germane), DEAG (di(ethylamino)germane), BDMAG (bis(dimethylamino)germane), BDEAG (bis(diethylamino)germane), and 3DMAG (tris(dimethylamino)germane).

The thermal processing gas used for thermally processing the substrate 100 at the first temperature and the second temperature may be an inert gas, such as nitrogen, argon, or the like, or may be a forming gas.

### [Substrate Processing Apparatus]

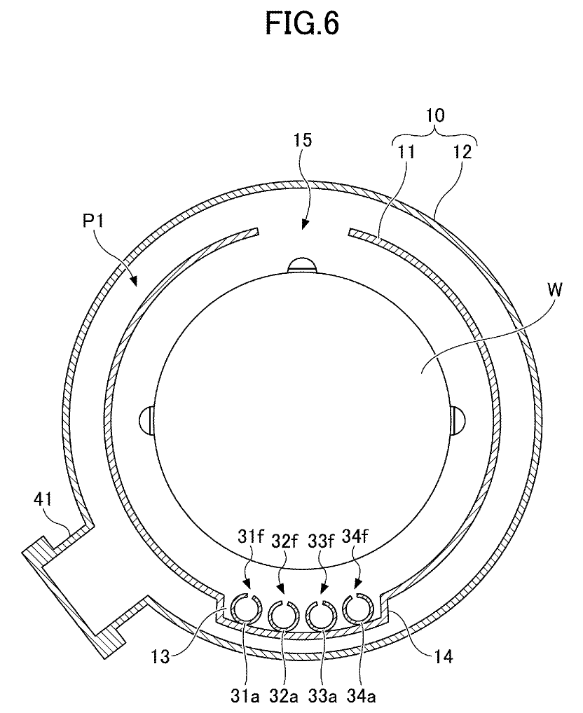

A substrate processing apparatus 1, according to an embodiment of the present disclosure, configured to perform the substrate processing method according to the embodiment will be described with reference to FIGS. 5 and 6. FIG. 5 is a vertical cross-sectional diagram illustrating the substrate processing apparatus 1 according to the embodiment. FIG. 6 is a horizontal cross-sectional diagram illustrating the substrate processing apparatus 1 according to the embodiment.

The substrate processing apparatus 1 is a batch-type apparatus configured to process a plurality of substrates W at one time. The substrates W are, for example, semiconductor wafers. The substrate processing apparatus 1 includes a processing chamber 10, a gas supply 30, a gas exhauster 40, a heater 50, and a controller 90.

The internal pressure of the processing chamber 10 can be reduced. The processing chamber 10 is configured to house the substrates W. The processing chamber 10 includes an inner tube 11 and an outer tube 12. The inner tube 11 has a cylindrical shape having a ceiling and an opened bottom end. The outer tube 12 has a cylindrical shape having a ceiling and an opened bottom end, and covers the outside of the inner tube 11. The inner tube 11 and the outer tube 12 are formed of a heat-resistant material, such as quartz or the like. The inner tube 11 and the outer tube 12 have a double-tube structure in which they are arranged coaxially.

The side wall of the inner tube 11 is provided with a housing 13 configured to house a gas supply tube along the longitudinal direction (vertical direction) of the inner tube 11. For example, a part of the side wall of the inner tube 11 is projected outward to form a projecting portion 14, and the interior of the projecting portion 14 is formed as the housing 13.

The side wall of the inner tube 11 is provided with a rectangular opening 15 that is along the longitudinal direction of the inner tube 11. The opening 15 faces the housing 13.

The opening 15 is a gas exhaust opening formed to allow the gas in the inner tube 11 to be exhausted. The length of the opening 15 is the same as the length of a boat 16, or is longer than the length of the boat 16, specifically, the opening 15 is formed to vertically extend beyond both vertical ends of the boat 16.

The bottom end of the processing chamber 10 is supported by a cylindrical manifold 17. The manifold 17 is formed, for example, of stainless steel. A flange 18 is formed at the top end of the manifold 17. The flange 18 supports the bottom end of the outer tube 12. A sealing 19, such as an O-ring or the like, is provided between the flange 18 and the bottom end of the outer tube 12. Thus, the interior of the outer tube 12 is maintained to be airtight.

The inner wall of the upper portion of the manifold 17 is provided with an annular support 20. The support 20 supports the bottom end of the inner tube 11. A cover 21 is airtightly attached to an opening at the bottom end of the manifold 17 via a sealing 22, such as an O-ring or the like. Thus, the opening at the bottom end of the processing chamber 10, i.e., the opening of the manifold 17, is airtightly closed. The cover 21 is formed, for example, of stainless steel.

The center portion of the cover 21 is provided, via a magnetic fluid seal 23, with a rotating shaft 24 that penetrates through the cover 21. The lower portion of the rotating shaft 24 is rotatably supported by an arm 25A of a raising and lowering mechanism 25 that is implemented by a boat elevator.

The top end of the rotating shaft 24 is provided with a rotating plate 26. A boat 16 configured to hold the substrates W is placed over the rotating plate 26 via a temperature-retaining stage 27 formed of quartz. The boat 16 is rotated by rotating the rotating shaft 24. The boat 16 is vertically moved integrally with the cover 21 by raising and lowering the raising and lowering mechanism 25. Thus, the boat 16 is inserted into and removed from the processing chamber 10. The boat 16 can be housed in the processing chamber 10. The boat 16 holds the substrates W (e.g., 50 to 150 substrates) at intervals in a vertically stacked manner. The boat 16 substantially horizontally holds the substrates W at intervals in the vertical direction.

The gas supply 30 is configured to introduce various gases into the inner tube 11. The gas supply 30 includes a silicon raw material gas supply 31, a germanium raw material gas supply 32, an oxidizing gas supply 33, and a thermal processing gas supply 34.

The silicon raw material gas supply 31 includes a gas supply tube 31a in the processing chamber 10, and a supply path 31b outside the processing chamber 10. The supply path 31b includes a silicon raw material gas source 31c, a mass flow controller 31d, and a valve 31e in order from upstream to downstream in the gas flow direction. Thus, the supply timing of the silicon raw material gas in the silicon raw material gas source 31c is controlled by the valve 31e, and the flow rate of the silicon raw material gas is adjusted to a predetermined flow rate by the mass flow controller 31d. The silicon raw material gas flows into the gas supply tube 31a from the supply path 31b, and is discharged into the processing chamber 10 from the gas supply tube 31a.

The germanium raw material gas supply 32 includes a gas supply tube 32a in the processing chamber 10, and a supply path 32b outside the processing chamber 10. The supply path 32b includes a germanium raw material gas source 32c, a mass flow controller 32d, and a valve 32e in order from upstream to downstream in the gas flow direction. Thus, the supply timing of the germanium raw material gas in the germanium raw material gas source 32c is controlled by the valve 32e, and the flow rate of the germanium raw material gas is adjusted to a predetermined flow rate by the mass flow controller 32d. The germanium raw material gas flows into the gas supply tube 32a from the supply path 32b, and is discharged into the processing chamber 10 from the gas supply tube 32a.

The oxidizing gas supply 33 includes a gas supply tube 33a in the processing chamber 10, and a supply path 33b outside the processing chamber 10. The supply path 33b includes an oxidizing gas source 33c, a mass flow controller 33d, and a valve 33e in order from upstream to downstream in the gas flow direction. Thus, the supply timing of the oxidizing gas in the oxidizing gas source 33c is controlled by the valve 33e, and the flow rate of the oxidizing gas is adjusted to a predetermined flow rate by the mass flow controller 33d. The oxidizing gas flows into the gas supply tube 33a from the supply path 33b, and is discharged into the processing chamber 10 from the gas supply tube 33a.

The thermal processing gas supply 34 includes a gas supply tube 34a in the processing chamber 10, and a supply path 34b outside the processing chamber 10. The supply path 34b includes a thermal processing gas source 34c, a mass flow controller 34d, and a valve 34e in order from upstream to downstream in the gas flow direction. Thus, the supply timing of the thermal processing gas in the thermal processing gas source 34c is controlled by the valve 34e, and the flow rate of the thermal processing gas is adjusted to a predetermined flow rate by the mass flow controller 34d. The thermal processing gas flows into the gas supply tube 34a from the supply path 34b, and is discharged into the processing chamber 10 from the gas supply tube 34a.

The gas supply tubes 31a, 32a, 33a, and 34a are fixed to the manifold 17. The gas supply tubes 31a, 32a, 33a, and 34a are formed, for example, of quartz. The gas supply tubes 31a, 32a, 33a, and 34a vertically extend in a straight line near the inner tube 11, and bend in an L shape in the manifold 17 and horizontally extend to penetrate through the manifold 17. The gas supply tubes 31a, 32a, 33a, and 34a are provided side by side along the circumferential direction of the inner tube 11 and are formed at the same height.

A plurality of discharge holes 31f, 32f, 33f, and 34f are provided at portions of the gas supply tubes 31a, 32a, 33a, and 34a that are positioned in the inner tube 11. The discharge holes 31f, 32f, 33f, and 34f are formed at predetermined intervals along the extending direction of the gas supply tubes 31a, 32a, 33a, and 34a. The discharge holes 31f, 32f, 33f, and 34f horizontally discharge gas toward the substrate W from the outside in the radial direction of the substrate W. The discharge holes 31f, 32f, 33f, and 34f discharge gas parallel to the main surface of the substrate W. The distance between the discharge holes is set, for example, to be equal to the distance between the substrates W held by the boat 16. The position of each discharge hole in the height direction is set, for example, at the middle position between the substrates W that are next to each other in the vertical direction. In this case, each discharge hole can efficiently supply gas to a facing surface between the substrates W next to each other.

The gas supply 30 may mix two or more types of gases together, and discharge the mixed gas from a single gas supply tube. The gas supply tubes 31a, 32a, 33a, and 34a may have different shapes and arrangements. The gas supply 30 may further include a gas supply tube configured to supply a different type of gas, e.g., an inert gas.

The gas exhauster 40 is configured to exhaust the gas that is discharged through the opening 15 from the interior of the inner tube 11 and then discharged from a gas outlet 41 through a space P1 between the inner tube 11 and the outer tube 12. The gas outlet 41 is formed at the side wall upward of the manifold 17 and above the support 20. A gas exhaust path 42 is connected to the gas outlet 41. A pressure regulating valve 43 and a vacuum pump 44 are sequentially disposed in the gas exhaust path 42 with a gap such that the internal gas of the processing chamber 10 can be exhausted.

The heater 50 is provided around the outer tube 12. The heater 50 is provided, for example, over a base plate 28. The heater 50 has a cylindrical shape to cover the outer tube 12. The heater 50 includes, for example, a heat generator, and is configured to heat the substrates W in the processing chamber 10.

The controller 90 is an electronic circuit or circuitry, such as a central processing unit (CPU), a graphics processing unit (GPU), a field programmable gate array (FPGA), an application specific integrated circuit (ASIC), or the like. The controller 90 is configured to execute various controls described in the present specification by executing instruction codes stored in a memory or by being designed as a circuit for specific applications.

How the substrate processing apparatus 1 is driven when the substrate processing apparatus 1 performs the substrate processing method according to the embodiment will be described. First, the controller 90 controls the raising and lowering mechanism 25 to carry into the processing chamber 10 the boat 16 holding the plurality of substrates W, and airtightly close the opening at the bottom end of the processing chamber 10 by the cover 21. The plurality of substrates W include the above-described substrate 100. Subsequently, the controller 90 controls the gas supply 30, the gas exhauster 40, and the heater 50 to perform the substrate processing method according to the embodiment. Thus, the silicon film 130 can be selectively crystallized relative to the silicon film 110. Subsequently, the controller 90 controls the gas exhauster 40 to increase the internal pressure of the processing chamber 10 to the atmospheric pressure, and then controls the raising and lowering mechanism 25 to carry the boat 16 out of the processing chamber 10.

In this manner, the substrate processing method according to the embodiment can be performed in the substrate processing apparatus 1.

The embodiments disclosed herein should be considered to be exemplary in all respects, not to be restrictive. Omissions, substitutions, and modifications may be made in various forms to the above-described embodiments without departing from the scope and intent of the claims recited.

Although the above embodiments have been described based on the case in which the first silicon-containing film and the second silicon-containing film are of the same film type, the present disclosure is not limited to this. The first silicon-containing film and the second silicon-containing film may be of different film types. For example, the first silicon-containing film may contain at least one selected from p-type impurities (e.g., boron (B)) and n-type impurities (e.g., phosphorus (P)). For example, the second silicon-containing film may contain at least one selected from p-type impurities (e.g., boron (B)) and n-type impurities (e.g., phosphorus (P)). For example, the first silicon-containing film and the second silicon-containing film may each independently contain carbon (C). For example, the first silicon-containing film and the second silicon-containing film may each independently contain germanium (Ge) at a concentration lower than in the germanium film 150.

Although the above embodiments have been described based on the case in which the first film is the germanium film, the present disclosure is not limited to this. The first film may be any film as long as it has a crystallization temperature that is lower than the crystallization temperature of the first silicon-containing film and the crystallization temperature of the second silicon-containing film. For example, the first film contains germanium. For example, the first film may be a silicon germanium film that is amorphous.

Although the above embodiments have been described based on the case in which the insulating film is a silicon oxide film, the present disclosure is not limited to this. The insulating film may be a silicon nitride film or a high dielectric constant (high-k) film.

Although the above embodiments have been described based on the case in which the substrate processing apparatus is a batch-type apparatus configured to process a plurality of substrates at one time, the present disclosure is not limited to this. For example, the substrate processing apparatus may be a single-wafer type apparatus configured to process substrates one by one. For example, the substrate processing apparatus may be a semi-batch-type apparatus configured to process a plurality of substrates disposed on a rotation table in a processing chamber by moving the substrates in accordance with rotation of the rotation table to cause the substrates to sequentially pass through a plurality of processing regions.

According to the present disclosure, it is possible to selectively crystallize a silicon-containing film.

What is claimed is:

1. A substrate processing method, comprising:
providing a substrate including a first film that is amorphous, a first silicon-containing film that is amorphous and is not in contact with the first film, and a second silicon-containing film that is amorphous and is in contact with the first film, a crystallization temperature of the first film being lower than a crystallization temperature of the first silicon-containing film; and
thermally processing the substrate at a temperature that is equal to or higher than the crystallization temperature of the first film and lower than the crystallization temperature of the first silicon-containing film.

2. The substrate processing method according to claim 1, wherein
the thermal processing of the substrate includes
thermally processing the substrate at a first temperature, and
thermally processing the substrate thermally processed at the first temperature, at a second temperature higher than the first temperature.

3. The substrate processing method according to claim 1, wherein
the provision of the substrate includes
forming an insulating film over the first silicon-containing film,
forming the second silicon-containing film over the insulating film, and
forming the first film over the second silicon-containing film.

4. The substrate processing method according to claim 3, wherein
the first silicon-containing film includes a top surface and a side surface continuous with the top surface, and
the insulating film is formed to cover the top surface and the side surface of the first silicon-containing film.

5. The substrate processing method according to claim 1, wherein
the first silicon-containing film and the second silicon-containing film are of same film type.

6. The substrate processing method according to claim 5, wherein
each of the first silicon-containing film and the second silicon-containing film is a silicon film.

7. The substrate processing method according to claim 1, wherein
the first film contains germanium.

8. The substrate processing method according to claim 7, wherein
the first film is a germanium film or a silicon germanium film.

9. A substrate processing apparatus, comprising:
a processing chamber configured to house a substrate;
a heater configured to heat the substrate housed in the processing chamber; and
a controller including circuitry, wherein
the circuitry is configured to control the substrate processing apparatus to house, in the processing chamber, the substrate including a first film that is amorphous, a first silicon-containing film that is amorphous and is not in contact with the first film, and a second silicon-containing film that is amorphous and is in contact with the first film, a crystallization temperature of the first film being lower than a crystallization temperature of the first silicon-containing film, and
the circuitry is configured to control the heater to thermally process the substrate at a temperature that is equal to or higher than the crystallization temperature of the first film and lower than the crystallization temperature of the first silicon-containing film.
